(19) United States
(12) Patent Application Publication
(10) Pub. No.: US 2020/0236803 A1
(43) Pub. Date: Jul. 23, 2020

(54) COVER FILM

(71) Applicant: GUNZE LIMITED, Ayabe-shi (JP)

(72) Inventors: Keisuke MATSUBARA, Moriyama-shi (JP); Takuya IKEDA, Moriyama-shi (JP)

(21) Appl. No.: 16/748,622

(22) Filed: Jan. 21, 2020

(30) Foreign Application Priority Data
Jan. 22, 2019 (JP) 2019-008860

(51) Int. Cl. H05K 5/03; H05K 5/00

(52) U.S. Cl. CPC H05K 5/03; H05K 5/0017

(57) ABSTRACT

Provided is a cover film for a bending display with which bending resistance thereof can be improved. The present invention provides a cover film for a bending display, and the cover film includes a transparent resin layer containing an ionizing radiation curable resin, the transparent resin layer has a thickness of 200 μm or less, and an end surface of the transparent resin layer has a line roughness Ra of 3.0 μm or less.

### TECHNICAL FIELD

The present invention relates to a cover film and a method for manufacturing the same.

### BACKGROUND ART

In recent years, various cover films for protecting surfaces of displays of smartphones and the like have been proposed JP 2003-292828A proposes a coves film having a film base material and a hard coat layer formed on the surface of the film base material, for example. Also, JP 2018-220622 proposes a foldable display film constituted by a cured film made of an ultraviolet curable acrylic resin having good flexibility.

JP 2003-292828A and JP 2018-22062A are examples of related art.

### SUMMARY OF THE INVENTION

Although there is increasing demand for cover films for bending displays to have durability in repeated bending, the performance thereof is not sufficient, and thus there is room for improvement. The present invention was made to resolve the above-described issues, and an object of the present invention is to provide a cover film for a bending display with which bending resistance thereof can be improved.

Aspect 1. A cover film for a bending display, including

a transparent resin layer containing an ionizing radiation curable resin,

in which the transparent resin layer has a thickness of 200 μm or less, and an end surface of the transparent resin layer has a line roughness Ha of 3.0 μm or less.

Aspect 2. The cover film according to Aspect 1, in which the cover film has a surface pencil hardness of H or more.

Aspect 3. A method for manufacturing a cover film, comprising:

forming a cover film having a transparent resin layer containing an ionizing radiation curable resin; and

cutting the cover film,

wherein the cover film has a thickness of 200 μm or less, and

an end surface of the transparent resin layer has a line roughness Ra of 3.0 μm or less.

Aspect 4. The method for manufacturing a cover film according to Aspect 3,

wherein. the end surface is cut using a laser.

Aspect 5. A method for manufacturing a cover film, including:

forming a cover film having a transparent resin layer containing an ionizing radiation curable resin and a protective film to be disposed on at least one surface of the cover film; and

emitting laser, and cutting the cover film, from the side on which the protective film is disposed,

in which the cover film has a thickness of 200 μm or less, and

an end surface of the transparent resin layer has a line roughness Ra of 3.0 μm or less.

The cover film according to the present invention. makes it possible to improve bending resistance.

### BRIEF DESCRIPTION OF THE DRAWINGS

FIG. 1 is a cross-sectional view showing an example of a method for manufacturing a cover film according to the present invention.

FIG. 2 is a cross-sectional view showing an example of the method for manufacturing a cover film according to the present invention.

FIG. 3 is a cross-sectional view showing an example of the method for manufacturing a cover film according to the present Invention.

FIG. 4 is a cross-sectional view showing an example of the method for manufacturing a cover film according to the present invention.

FIG. 5A is a diagram (plan view) illustrating a bending direction and line roughness.

FIG. 5B is a diagram (side view) illustrating a bending direction. and line roughness.

FIG. 6A is a schematic diagram (initial position) showing a bending tester and a method for using the bending tester.

FIG. 6B is a schematic diagram (bending position) showing a bending tester and a method for using the bending tester.

### EMBODIMENTS OF THE INVENTION

1. Overview of Cover Film

Hereinafter, one embodiment of a cover film according to the present invention will be described. The cover film according to the present invention includes a transparent resin layer. Hereinafter, the cover film. according to the present invention. will be described in. detail. Note that, in. this specification, numerical values connected using “˜” refer to a numerical range including numerical values written in front of and after “˜” as the lower limit and the upper limit. Also, if a plurality of lower limits and a plurality of upper limits are written separately, any lower limit and any upper limit may be selected and connected using “˜”.

2. Transparent Resin Layer

The transparent resin layer is obtained by curing a resin composition for forming a transparent resin layer containing an ionizing radiation curable resin, a photopolymerization initiator, and the like. Also, an additive, which will be described later, can be added to this composition as needed.

2-1. Ionizing Radiation Curable Resin

The ionizing radiation curable resin to be used for a transparent resin layer preferably contains a polyfunctional (meth) acrylate having a total of three or more methacryloyl groups and acryloyl groups. There is no particular limitation on a skeletal structure other than the (meth) acrylol group of the polyfunctional (meth) acrylate, and an ionizing radiation curable resin having a silicone-based, urethane-based, epoxy-based, fluorine-based, and aliphatic skeletal structure can be used, for example.

A polyfunctional silicone-based resin containing, as the main component, cage-type polyorganosilsesquioxane in which an organic functional group having a (meth) acryloyl group is bonded to silicon can be used as the ionizing radiation resin because a transparent resin layer that has high surface hardness, is flexible, and is unlikely to crack can be produced. Also, a polymerizable composition containing a polyfunctional urethane-based (meth) acrylate and/or a polyfunctional aliphatic (meth) acrylate may be used, instead of a silicone-based resin. Also, the above-described urethane-based (meth) acrylate and/or (meth) acrylate may be mixed with the silicone-based resin. 100 to 500 parts by weight, preferably 200 to 400 parts by weight of a urethane-based (meth) acrylate and/or aliphatic (meth) acrylate can be mixed with 100 parts by weight of a silicone-based resin, for example.

Polyorganosilsesquioxanes are compounds having a (RSiO1.5)n structure obtained through hydrolysis of trifunctional silane, and it is preferable to use Polyorganosiysesquioxanes having a cage structure in the present invention. That is, a cage-type polyorganosilsesquioxane has a cage-like skeleton constituted by an organic functional group and a Si—O bonding resulting from each silicon (Si) atom being bonded to one hydrocarbon group (R) and an average of 1.5 oxygen (O) atoms. Such a structure increases the hardness of a cured transparent resin layer Also, it is preferable that the number of silicon (Si) atoms (the above-described n) is 8, 10, or 12 in a cage-type polyorganosilsesquioxane.

Urethane-based (meth) acrylates are preferable because an urethane-based (meth) acrylate is formed through a reaction between a polyisocyanate compound and a hydroxy group-containing (meth) acrylate, and hydrogen bonds of the urethane group in the molecule impart appropriate toughness thereto so that the urethane-based (meth) acrylate has high mechanical strength, and a resin molded article having high hardness can be obtained because the urethane-based (meth) acrylate is polyfunctional and thus is cured to form a crosslinking structure. The number average molecular weight of a urethane-based (meth) acrylate is preferably 200 to 5,000. If the number average molecular weight is less than 200, there is a risk that cure shrinkage will increase and birefringence will be likely to occur . If the number average molecular weight exceeds 5,000, there is a risk that crosslinkability will decrease and heat resistance will become insufficient.

Although there is no particular limitation on the polyisocyanate compound and examples thereof include aliphatic polyisocyanates, aromatic polyisocyanates, and aromatic-aliphatic polyisocyanates, it is preferable to use an aliphatic polyisocyanate in terms of capable of inhibiting yellowing. Also, it is preferable to use, as a polyisocyanate compound, a compound that has no alicyclic structure because it is possible to obtain a transparent resin layer that particularly has good surface hardness. Examples of the aliphatic polyisocyanate include trimethylene diisocyanate, tetramethylene diisocyanate, hexamethylene diisocyanate (HDI) pentamethylene diisocyanate, 1,2-propylene diisocyanate, 2,3-butylene diisocyanate, 1,3-butylene diisocyanate, dodecamethylene diisocyanate, 2,4,4-trimethylhexamethylene diisocyanate, lysine isocyanate, hydrogenated xylene diisocyanate, hydrogenated diphenylmethane diisocyanate, 1,3-bis (diisocyanatemethyl) cyclohexane, and 4,4′-dicyclohexylmethane diisocyanate.

Although there is no limitation on the hydroxy group-containing (meth) acrylate as long as the molecule has a hydroxy group and a (meth) acryloyl group, examples thereof include 2-hydroxyethyl (meth) acrylate, 2-hydroxylpropyl (meth) acrylate, 2-hydroxybutyl (meth) acrylate, 2-hydroxy-3-(meth) acryloyloxypropyl (meth) acrylate, pentaerythritol tri (meth) acrylate, dipentaerythritol penta (meth) acrylate, dipentaerythritol tri (meth) acrylate, and tnipentaerythritol heptaacrylate. In particular, it is preferable to use a hydroxy group-containing (meth) acrylate that has no alicyclic structure in its molecule in terms of inhibiting a change in surface hardness and tint of a transparent resin layer.

(Meth) acrylates of aliphatic polyhydric alcohols can be used as the aliphatic (meth) acrylate, and examples thereof include trifunctional (meth)acrylates such as 1,3,5-tris(methacryloyloxymethyl)cyclohexane and 1,3,5-tris(methacryloyloxyethyloxymethyl)cyclohexane.

2-2. Photopolymerization Initiator

Examples of a polymerization initiator include benzyl methyl ketals such as 2,2-dimethoxy-1,2-diphenylethan-1-one, α-hydroxyl ketones such as 1-hydroxycyclohexyl phenyl ketone and 2-hydroxy-2-methyl-1-phenylpropan-1-one, α-aminoketones such as 2-methyl-1[4-(methylthio)phenyl]-2-morpholinopropan-1-one, and 2-benzyl-2-dimethylamino-1-(4-morpholinophenyl)-1-butanone, bisacylphosphine oxides such as bis(2,6-dimethoxybenzoyl)-2,4,4-trimethylpentyl phosphine oxide, bisimidazoles such as 2,2′-bis(o-chlorophenyl)-4,4′,5,5′-tetraphenyl-1,1′-biimida zole and bis(2,4,5-triphenyl)imidazole, N-allyiglycines such as N-phenylglycine, organic azides such as 4,4′-diazide chalcone, and organic peroxides such as 3,3′,4,4′-tetra(tert-butylperoxycaiboxyl)benzophenone as well as compounds cited in J. Photochem. Sci. Technol., 2, 283(1987).

Specific examples thereof include iron arene complexes, trihalogenomethyl-substituted S-triazine, sulfonium salts, diazonium salts, phosphonium salts, selenonium salts, arsonium salts, and iodonium salts. Also, examples of the iodonium salt include compounds cited in Macromolecules, 10, 1307 (1977) , such as chlorides and bromides of iodonium (e.g., diphenyliodonium, ditolyliodonium, phenyl (p-anisyl) iodonium, his (m-nitrophenyl) iodonium, bis (p-tert-butylphenyl) iodonium, and bis (p-chlorophenyi) iodonium) , fluoroborates, hexafluorophosphates, hexafluoroarsenates, and aromatic sulfonates, and sulfonium organoboron complexes such as diphenylphenacyl sulfonium (n-butyl) triphenylborate.

2-3. Additives

An additive can be mixed in a resin composition for forming a transparent resin layer as needed. Examples thereof include a silicone-based additive and a fluorine-based additive (for example, a leveling agent) for imparting leveling, a surface slip property, a low water contact angle property, and the like, for example. As a result of adding such an additive, scratch resistance of the surface of the transparent resin layer can be improved.

3. Physical Properties of Transparent Resin Layer

The transparent resin layer has a thickness of 20 μm to 200 μm inclusive, and the lower limit is preferably 50 μm or more, and more preferably 75 μm or more. Also, the upper limit is preferably 180 μm or less, and more preferably 150 μm or less. This is because if a transparent resin layer has a thickness of less than 20 μm, the pencil hardness of the surface thereof significantly decreases, and a transparent resin layer having a thickness of more than 200 μm is not preferable in terms of flexibility.

Also, the transparent resin layer preferably has a surface pencil hardness of H or more, and more preferably has a surface pencil hardness of 2H or more, in a surface pencil hardness test defined in JIS5600-5-4 (1999) .

4. Method for Manufacturing Cover Film

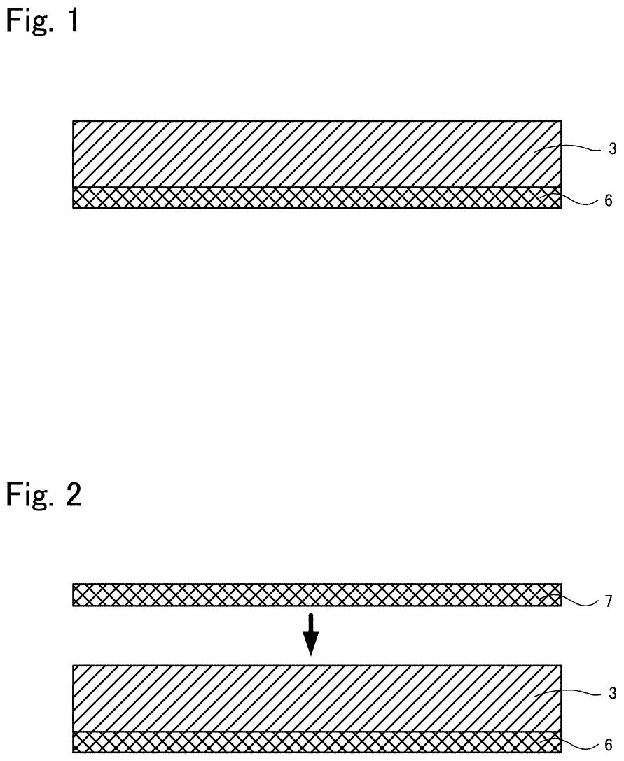

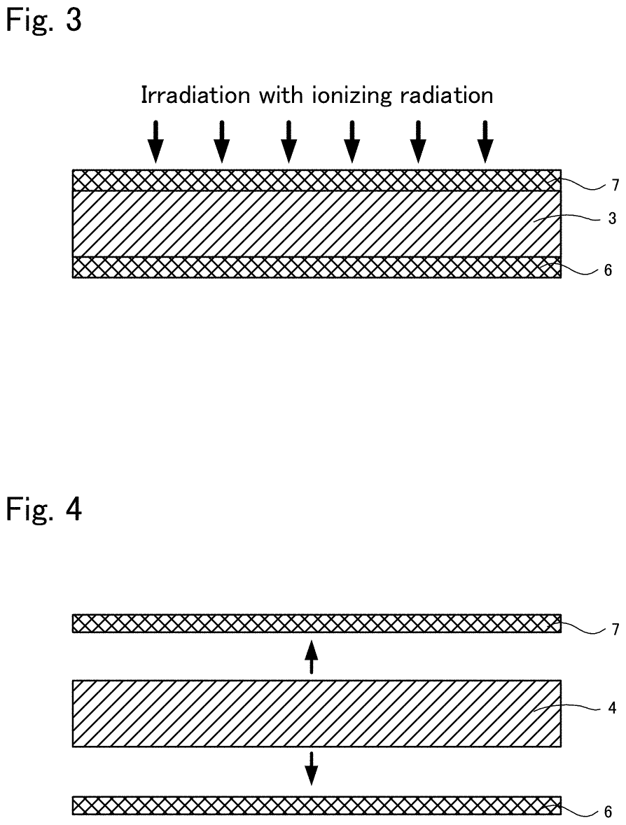

A method for manufacturing a cover film according to the present invention will be described with reference to the drawings. FIG. 1 is a diagram showing the method for manufacturing a cover film according to an embodiment of the present invention, FIG. 1 showing an applying process, FIG. 2 showing a stacked member producing process, FIG. 3 showing an ionizing radiation irradiation process, and FIG. 4 showing a separating process.

As shown in FIG. 1, the above-described resin composition for forming a transparent resin layer is applied onto a first base film (protective film) 6 to form a transparent. resin layer precursor 3 thereon in the applying process.

As shown in FIG. 2, in the stacked member producing process, a second base film (protective film) 7 is stacked on the transparent resin layer precursor 3 to obtain a stacked member in which the first base film 6, the transparent resin layer precursor 3, and the second base film 7 are stacked in that order. Note that a commercially available PET film or the like can be used as the base films 6 and 7. Also, although the second base film 7 is not necessarily required, the smoothness of the transparent resin layer can be improved as a result of providing the second base film 7.

As shown in FIG. 3, the ionizing radiation curable resin is cured (photoradically polymerized) by irradiating the stacked member with ionizing radiation (e.g., ultraviolet rays) in the ionizing radiation irradiation process.

As shown in FIG. 4, both base films 6 and 7 are separated therefrom in the separating process. An uncured ionizing radiation curable resin that constitutes the transparent resin layer precursor 3 is photoradically polymerized to form the transparent resin layer 4, that is, the cover film. of this embodiment, in the series of processes.

5. Cutting Cover Film (Trimming)

The cover film manufactured as described above is cut to a desired size and then used. The cover film can be cut using a laser or a cutting machine. Note that this trimming is preferably performed before the above-described separating process.

From this point of view, the end surface of the transparent resin layer 4 that has been cut in the above-described manner preferably has an arithmetic average line roughness Ra of 3.0 μm or less, more preferably 2.5 μm or less, even more preferably 1.5 μm or less, and particularly preferably 1.0 μm or less.

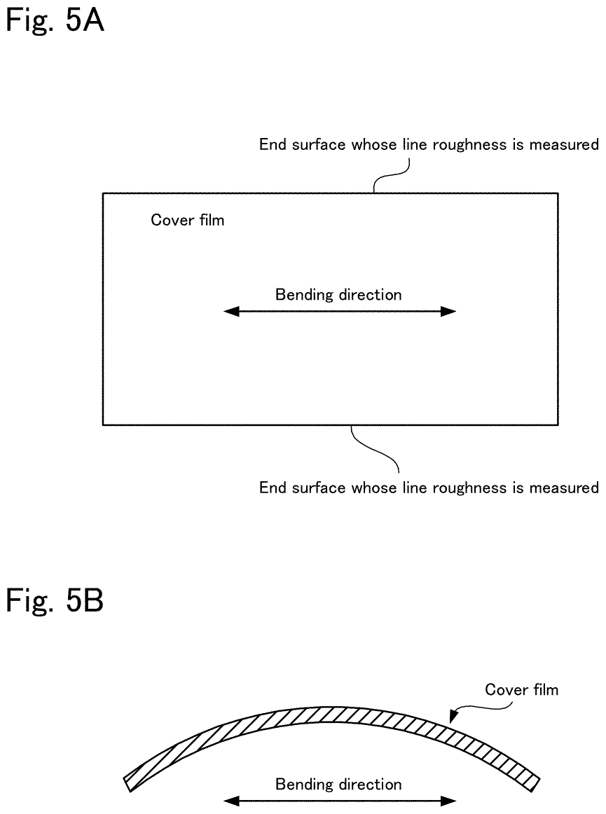

Also, as shown in FIGS. 5A and 5B, the line roughness Ra of the end surface refers to at least a line roughness of the end surface extending along a direction in which the cover film is bent (bending direction). Note that the bending direction usually refers to a long-side direction of the cover film in many cases, but may refer to a short-side direction. If the cover film is bent in both the long-side direction and the short-side direction, the direction in which the cover film is bent more is referred to as the bending direction. From this point of view, it is more preferable that an end surface extending in a direction orthogonal to the bending direction also has a line roughness Ra as described above. The line roughness Ra can be measured as described below, for example.

That is, an objective lens of a laser microscope is set to have a magnification of 50 times, and the end surface of the cut transparent resin layer (the end surface that is parallel to the bending direction) is observed. At this time, the line roughness Ra is measured at five different points (five points at approximately equal intervals) under a condition where the measurement length is 200 μm or more, and an average thereof is calculated. Note that, although it is preferable to calculate an average of the line roughnesses Ra at five points, for example, if it is difficult to make measurements, an average of the line roughnesses Ra at fewer than five points can be calculated, or the number of measurement points can also be set to one.

Note that, in order to reduce the line roughness Ra of the end surface of the transparent resin layer, it is preferable to perform cutting using a laser. Also, the cutting speed of the laser is not particularly limited, but can be set to 40 to 600 mm/sec, for example.

Also, if cutting is performed using a laser, it is preferable to perform cutting before the above-described base films 6 and 7 are separated, in order to protect the cover film from smoke generated during cutting. At this time, cutting can be also performed using a laser after only a base film opposite to the side to be irradiated with the laser is separated therefrom. Also, cutting can be performed after both base films 6 and 7 are separated in the above-described separating process and then another protective film is attached to at least one surface of the cover film. A protective film obtained by applying an adhesive layer to a base member made of a resin material such as PET can be used as the protective film, for example. The adhesive layer is attached to the transparent resin layer, and then cut using a laser.

6. Characteristics

With a cover film according to the present embodiment, by setting a line roughness Ra of an end surface of a transparent resin layer to 3.0 μm or less, bending performance can be improved. Thus, this cover film can be suitably used as a cover film for a bending display.

Note that a cover film according to the present invention can also be obtained by forming a fingerprint resistant film, a transparent conductive film, an antireflection film, and the like on at least one surface of the transparent resin layer.

### EXAMPLES

Next, examples of the present invention will be described. However, the present invention is not limited to the examples below.

1. Production of Examples and Comparative Examples

Hereinafter, production of cover films according to Examples 1 to 4 and Comparative Examples 1 and 2 will be described.

A transparent resin layer precursor was formed on a first base film (A4100 manufactured by TOYOBO CO. , LTD.) by applying a resin composition for forming a transparent resin layer obtained by adding 5 parts of a photopolymerization initiator (Omnirad1173 manufactured by IGM Resins B.V.) to 100 parts of ionizing radiation curable resin (NEW FRONTIER R1302XT manufactured by DKS Co., Ltd.) using a bar coater (ROD #75) manufactured by TESTER SANGYO CO., LTD. onto an unprocessed surface (a surface on which a highly adhesive layer is not formed) of the first base film such that the thickness of a cured film was 100 μm.

Production of Stacked Member

Then, a stacked member was produced by laminating another second base film (A4100 manufactured by TOYOBO CO., LTD.) on the transparent resin layer precursor such that an unprocessed surface of the second base film was in contact with the transparent resin layer precursor.

Ionizing Radiation Irradiation (Polymerization)

An ionizing radiation curable resin included in the transparent resin layer precursor was photoradically polymerized using an ultraviolet curing apparatus (CV-110Q-G manufactured by Fusion UV systems Japan K.K.) by irradiating the above-described stacked member with ultraviolet rays having a cumulative irradiation amount of 1500 mJ/cm².

Separating Process

The base films of both surfaces of the photoradically polymerized stacked member were separated to produce transparent resin layers according to examples and comparative examples.

A sample piece having a size of 1.0×9.0 cm was cut out from each of the examples and the comparative examples that were produced in the above-described manner, using a laser cutting apparatus (SpiritGX 30W manufactured by GCC Co., Ltd.) with conditions such as speed changed. The protective film was attached to both surfaces of the transparent resin layer, and then the sample piece was cut through irradiation with the laser. The protective film was a PET film in which adhesive layers that each had a thickness of 5 μm were stacked on each other and that. had a thickness of 100 μm, and the adhesive layers were attached to the transparent resin layer.

Also, while the output of the laser was 30 W, the sample pieces were cut out at 50% of 30 W. Also, the cutting speed of the laser was adjusted as shown in Table 1 where the speed was 2 m/sec, at 100%, and. the sample pieces were cut out.

Then, a line roughness Ra of the transparent resin layer of an end surface extending along a long side of the cutout sample piece was measured. The measurement method was the same as that described in the above-described embodiment.

2. Bending Resistance Evaluation Test

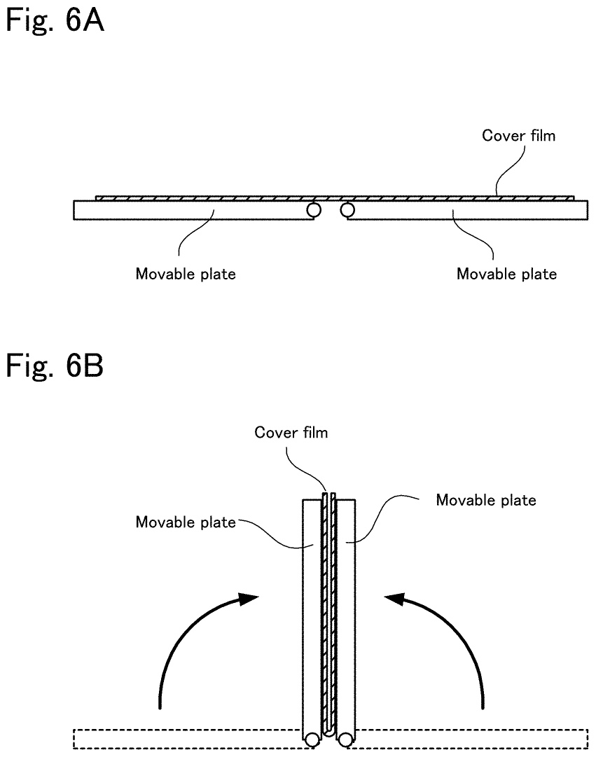

Then, each sample piece prepared in the above-described manner was repeatedly bent. using an unloaded U-shaped tester shown in FIGS. 6A and 6B at a test speed of 0.85 seconds in each. instance of bending. More specifically, this tester had two pivotable movable plates, and the rotation axes of the moveable plates were disposed close to each other such that the rotation axes were parallel to each other. Also, as shown in FIG. 6B, each sample piece was bent into a U-shape by pivoting both. movable plates by 90 degrees in a state in which the sample piece was disposed on the horizontal movable plates shown in FIG. 6A. Note that the sample piece was disposed on the tester such that the bending direction shown in FIG. 5 extended in the horizontal direction shown in FIG. 6. Also, after testing was performed, whether or not cracks had formed on the sample pieces was checked, and bending resistance was evaluated in the following A to C criteria.
A: No cracks formed under the conditions where the bending radius was R2.5 mm and the number of instances of bending was 100,000 or more.
B: No cracks formed under the conditions where the bending radius was R2.5 mm and the number of instances of bending was 10,000 or more.
C: Cracks formed under the conditions where the bending radius was R2.5 mm and the number of instances of bending was less than 10,000.

The results are as follows.

TABLE 1

| | | | Number of Cracks | Bending |
|---|---|---|---|---|
| | | Line | Formed in Bending | Test |
| | Laser Speed | Roughness Ra | Test | Evaluation |
| Ex. 1 | 3% (60 mm/sec) | 1.83 μm | 15,000 or more | B |
| Ex. 2 | 5% (100 mm/sec) | 0.93 μm | 100,000 or more | A |
| Ex. 3 | 12% (240 mm/sec) | 0.86 μm | 100,000 or more | A |
| Ex. 4 | 15% (300 mm/sec) | 0.74 μm | 100,000 | A |
| Comp. Ex. 1 | 0.5% (10 mm/sec) | 4.64 μm | 30 | C |
| Comp. Ex. 2 | 1% (20 mm/sec) | 4.48 μm | 200 | C |

3. Pencil Hardness Evaluation Test

A surface pencil hardness test conforming to JIS-K5600-5-4 was performed on the cover films of Examples 1 to 4 and Comparative Examples 1 and 2 above. That is, a test was performed using pencils with a hardness of H to 3H (Mitsubishi Pencil Co., Ltd.) in that order with a load of 750 q applied to the surface of the transparent resin layer. Then, a change in the appearance of the surface of the hard coat layer was visually evaluated. The results were all 2H.

What is claimed is:

1. A cover film for a bending display, comprising
a transparent resin layer containing an ionizing radiation curable resin,
wherein the transparent resin layer has a thickness of 200 μm or less, and
an end surface of the transparent resin layer has a line roughness Ra of 3.0 μm or less.

2. The cover film according to claim 1,
wherein the cover film has a surface pencil hardness of H or more.

3. A method for manufacturing a cover film, comprising:
forming a cover film having a transparent resin layer containing an ionizing radiation curable resin; and
cutting the cover film,
wherein the cover film has a thickness of 200 μm or less, and
an end surface of the transparent resin layer has a line roughness Ra of 3.0 μm or less.

4. The method for manufacturing a cover film according to claim 3,
wherein the end surface is cut using a laser.

5. A method for manufacturing a cover film, comprising:
forming a cover film having a transparent resin layer containing an ionizing radiation curable resin and a protective film to be disposed on at least one surface of the cover film; and
emitting a laser, and cutting the cover film, from the side on which the protective film is disposed,
wherein the cover film has a thickness of 200 μm or less, and
an end surface of the transparent resin layer has a line roughness Ra of 3.0 μm or less.
